(19) United States
(12) Patent Application Publication
(10) Pub. No.: US 2014/0048815 A1
(43) Pub. Date: Feb. 20, 2014

(54) SCHOTTKY BARRIER DIODE AND MANUFACTURING METHOD THEREOF

(71) Applicants: Tsung-Yi Huang, Hsinchu City (TW); Chien-Wei Chiu, Beigang Township (TW); Chih-Fang Huang, Hsinchu City (TW); Tsung-Yu Yang, Kaohsiung City (TW)

(72) Inventors: Tsung-Yi Huang, Hsinchu City (TW); Chien-Wei Chiu, Beigang Township (TW); Chih-Fang Huang, Hsinchu City (TW); Tsung-Yu Yang, Kaohsiung City (TW)

(73) Assignee: Richtek Technology Corporation

(21) Appl. No.: 13/589,784

(22) Filed: Aug. 20, 2012

(51) Int. Cl. H01L 29/872; H01L 21/329

(52) U.S. Cl. 257/76; 438/572; 257/E29.338; 257/E21.359

(57) ABSTRACT

A Schottky barrier diode (SBD) is disclosed, which includes: a gallium nitride (GaN) layer, formed on a substrate; an aluminum gallium nitride (AlGaN), formed on the GaN layer; an insulation layer, formed on the AlGaN layer; an anode conducive layer, formed on the insulation layer, wherein Schottky contact is formed between a part of the anode conductive layer and the AlGaN layer or between a part of the anode conductive layer and the GaN layer, and another part of the anode conductive layer is separated from the AlGaN layer by the insulation layer; and a cathode conductive layer, formed on the AlGaN layer, wherein an ohmic contact is formed between the cathode conductive layer and the GaN layer or between the cathode conductive layer and the AlGaN layer, and wherein the anode conductive layer is not directly connected to the cathode conductive layer.

### BACKGROUND OF THE INVENTION

1. Field of Invention

The present invention relates to a Schottky barrier diode (SBD) and a manufacturing method of an SBD; particularly, it relates to such SBD and manufacturing method wherein the leakage current of the SBD is decreased.

2. Description of Related Art

FIG. 1 shows a prior art Schottky barrier diode (SBD) 100 formed on a silicon substrate 11. The SBD 100 includes: a gallium nitride (GaN) layer 12, an aluminum gallium nitride (AlGaN) layer 13, an anode conductive layer 14, and a cathode conductive layer 15. Compared to a conventional P-N junction diode, the SBD 100 has a higher forward current and a shorter recovery time in operation because of a Schottky barrier formed by Schottky contact between a metal layer and a semiconductor layer. However, the SBD has a higher leakage current and therefore more power loss in a reverse biased operation.

To overcome the drawback in the prior art, the present invention proposes an SBD and a manufacturing method thereof which decrease the leakage current in the reverse biased operation, such that the power loss is decreased.

### SUMMARY OF THE INVENTION

A first objective of the present invention is to provide a Schottky barrier diode (SBD).

A second objective of the present invention is to provide a manufacturing method of an SBD.

To achieve the objectives mentioned above, from one perspective, the present invention provides a Schottky barrier diode (SBD) formed on a substrate, including: a gallium nitride (GaN) layer formed on the substrate; an aluminum gallium nitride (AlGaN) layer formed on the GaN layer; an insulation layer formed on the AlGaN layer; an anode conductive layer formed partially on the insulation layer, wherein a Schottky contact is formed between a part of the anode conductive layer and the GaN layer or between a part of the anode conductive layer and the AlGaN layer, and another part of the anode conductive layer is separated from the AlGaN layer by the insulation layer; and a cathode conductive layer, formed on the AlGaN layer, wherein an ohmic contact is formed between the cathode conductive layer and the GaN layer or between the cathode conductive layer and the AlGaN layer, and wherein the anode conductive layer is not directly connected to the cathode conductive layer.

From another perspective, the present invention provides a manufacturing method of an SBD, including: forming a gallium nitride (GaN) layer on a substrate; forming an aluminum gallium nitride (AlGaN) layer on the GaN layer; forming an insulation layer on the AlGaN layer; forming an anode conductive layer partially on the insulation layer, wherein a Schottky contact is formed between a part of the anode conductive layer and the GaN layer or between a part of the anode conductive layer and the AlGaN layer, and another part of the anode conductive layer is separated from the AlGaN layer by the insulation layer; and forming a cathode conductive layer on the AlGaN layer, wherein an ohmic contact is formed between the cathode conductive layer and the GaN layer or between the cathode conductive layer and the AlGaN layer, and wherein the anode conductive layer is not directly connected to the cathode conductive layer.

In one embodiment, the insulation layer preferably has a grid pattern from top view, and is formed between the anode conductive layer and the GaN layer or between the anode conductive layer and the AlGaN layer.

In another embodiment, the substrate preferably includes an insulator substrate or a conductor substrate.

In another embodiment, the insulation layer preferably has a thickness thinner than 1 micro-meter.

In another preferable embodiment, the insulation layer preferably has a dielectric constant higher than 3.9.

The objectives, technical details, features, and effects of the present invention will be better understood with regard to the detailed description of the embodiments below.

### BRIEF DESCRIPTION OF THE DRAWINGS

FIG. 1 shows a prior art Schottky barrier diode (SBD) 100.

FIG. 2 shows a first embodiment of the present invention.

FIG. 3 shows a second embodiment of the present invention.

FIGS. 4A-4C show a third embodiment of the present invention.

FIG. 5 shows a fourth embodiment of the present invention.

FIGS. 6A-6B show characteristic curves of the prior art SBD and the SBD according to the present invention, respectively.

FIGS. 7A-7B show simulations of the electric field of the prior art SBD and the SBD according to the present invention, respectively.

FIGS. 8A-8B show simulations of the electric field of the prior art SBD and the SBD according to the present invention, respectively.

FIGS. 9A and 9B show simulation diagrams of electric field in lateral direction of the SBDs according to the prior art and the present invention, respectively.

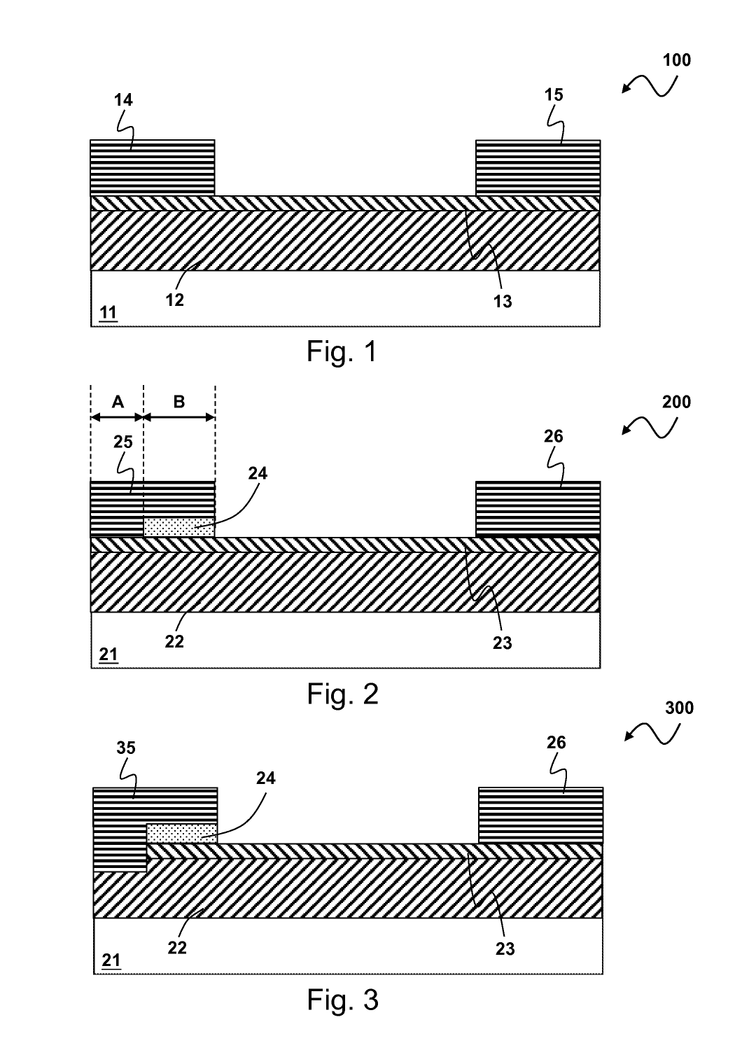

### DESCRIPTION OF THE PREFERRED EMBODIMENTS

The drawings as referred to throughout the description of the present invention are for illustration only, but not drawn according to actual scale.

FIG. 2 shows a first embodiment of the present invention. As shown in FIG. 2, an SBD 200 is formed on a substrate 21. The substrate 21 is for example but not limited to a silicon substrate, a conductor substrate such as a silicon carbide substrate, or an insulator substrate such as a sapphire substrate. A gallium nitride (GaN) layer 22 is formed on the substrate 21 by for example but not limited to an epitaxial growth step. Besides the GaN layer 22, the SBD 200 further includes: an aluminum gallium nitride (AlGaN) layer 23, an insulation layer 24, an anode conductive layer 25, and a cathode conductive layer 26. The AlGaN layer 23 is formed on the GaN layer 22. The insulation layer 24 is formed on the AlGaN layer 23. The anode conductive layer 25 is formed on the insulation layer 24, and a Schottky contact is formed between a part A of the anode conductive layer 25 and the AlGaN layer 23; another part B of the anode conductive layer 25 is separated from the AlGaN layer 23 by the insulation layer 24. The cathode conductive layer 26 is formed on the AlGaN layer 23. An ohmic contact is formed between the cathode conductive layer 26 and the AlGaN layer 23. The anode conductive layer 25 is not directly connected to the cathode conductive layer 26.

This embodiment is different from the prior art particularly in that, in this embodiment, the insulation layer 24 forms a plate with multiple electric fields, such that the Schottky barrier between the anode conductive layer 25 and the AlGaN layer 23 is adjusted to enhance the OFF breakdown voltage of the SBD 200.

FIG. 3 shows a schematic cross-section diagram of an SBD 300 according to a second embodiment of the present invention. This embodiment is different from the first embodiment in that, in this embodiment, a Schottky contact is formed between a part of the anode conductive layer 35 and the GaN layer 22 instead of between the anode conductive layer 35 and the AlGaN layer 23.

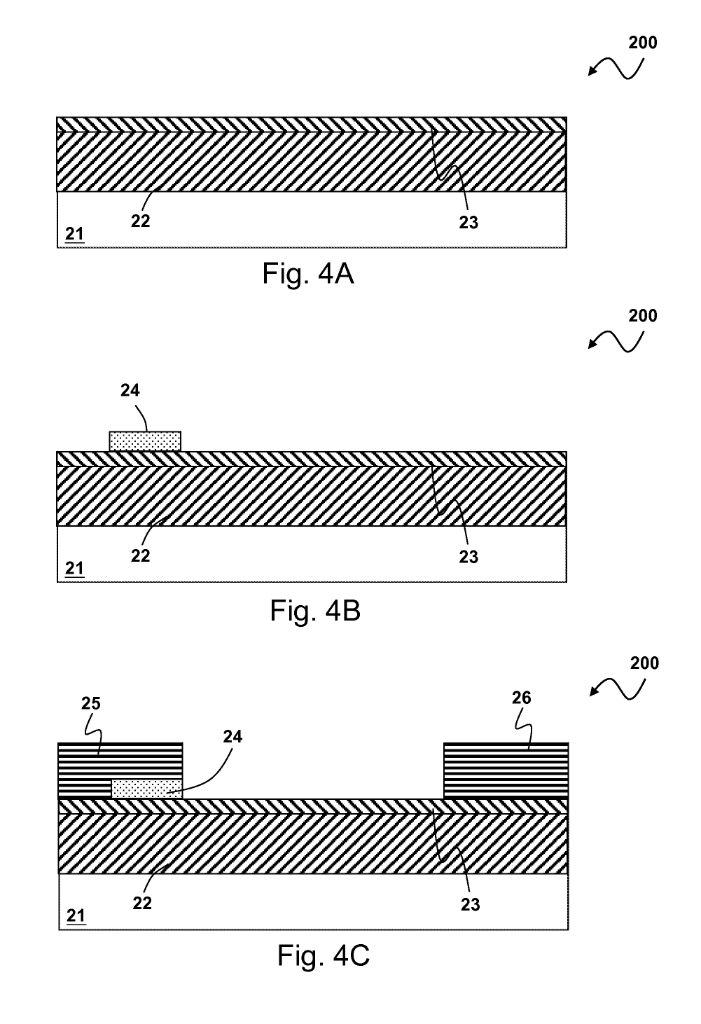

FIGS. 4A-4C are schematic cross-section diagrams of a third embodiment according to the present invention, showing a manufacturing flow of the SBD 200. As shown in FIG. 4A, the GaN layer 22 is formed on the substrate 21. The substrate 21 for example is but not limited to a sapphire substrate or a conductive substrate, such as a silicon carbide (SiC) substrate. Next, the AlGaN layer 23 is formed on the GaN layer 22.

Next, referring to FIG. 4B, the insulation layer 24 is formed on the AlGaN layer 23, wherein the insulation layer 24 is made of for example but not limited to a high dielectric constant material, which has a dielectric constant for example higher than 3.9 of the silicon dioxide.

Next, as shown in FIG. 4C, the anode conductive layer 25 is formed on the insulation layer 24, and the cathode conductive layer 26 is formed on the AlGaN layer 23. The Schottky contact is formed between a part of the anode conductive layer 25 and the AlGaN layer 23, and another part of the anode conductive layer 25 is separated from the AlGaN layer 23 by the insulation layer 24. An ohmic contact is formed between the cathode conductive layer 26 and the AlGaN layer 23, and the anode conductive layer 25 is not directly connected to the cathode conductive layer 26.

FIG. 5 shows a schematic cross-section diagram of an SBD 400 according to a fourth embodiment of the present invention. This embodiment is different from the first embodiment in that, in this embodiment, an insulation layer 34 which is formed between the anode conductive layer 25 and the GaN layer 22 has a grid pattern from top view (not shown).

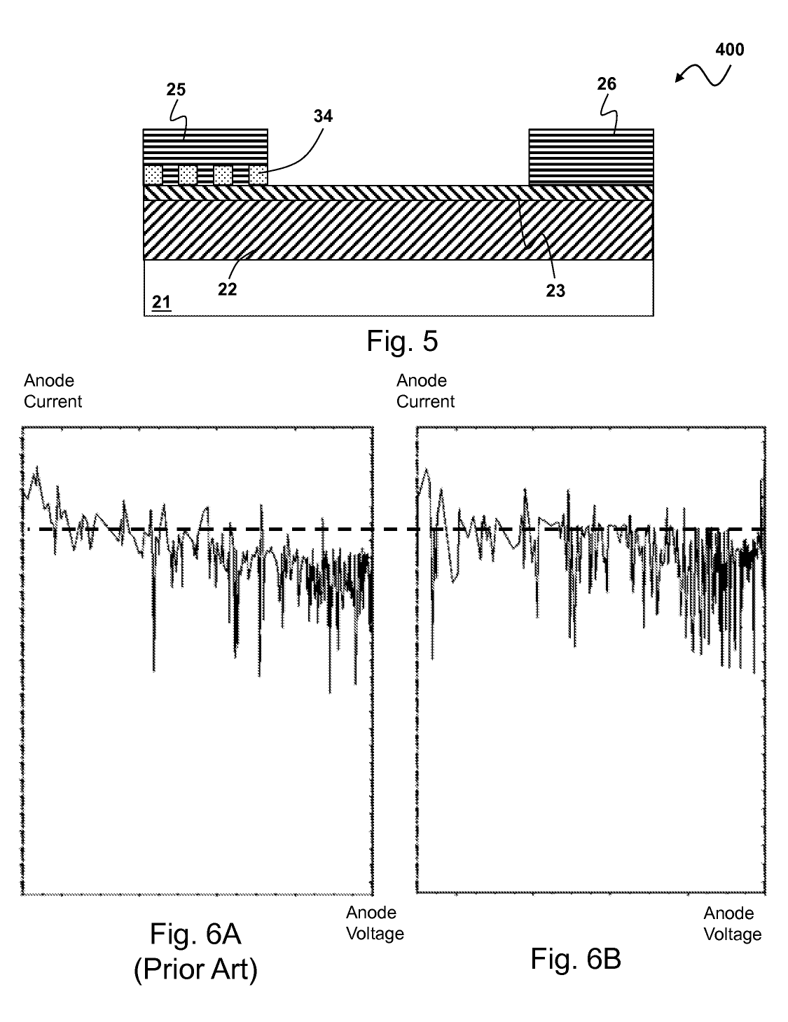

FIGS. 6A and 6B show characteristic curves of anode currents versus anode voltages of the prior art and the present invention, respectively. As shown in FIGS. 6A and 6B, the anode current of the present invention is higher than that of the prior art at the same anode voltage. This indicates that the ON resistance of the present invention is lower and better than that of the prior art.

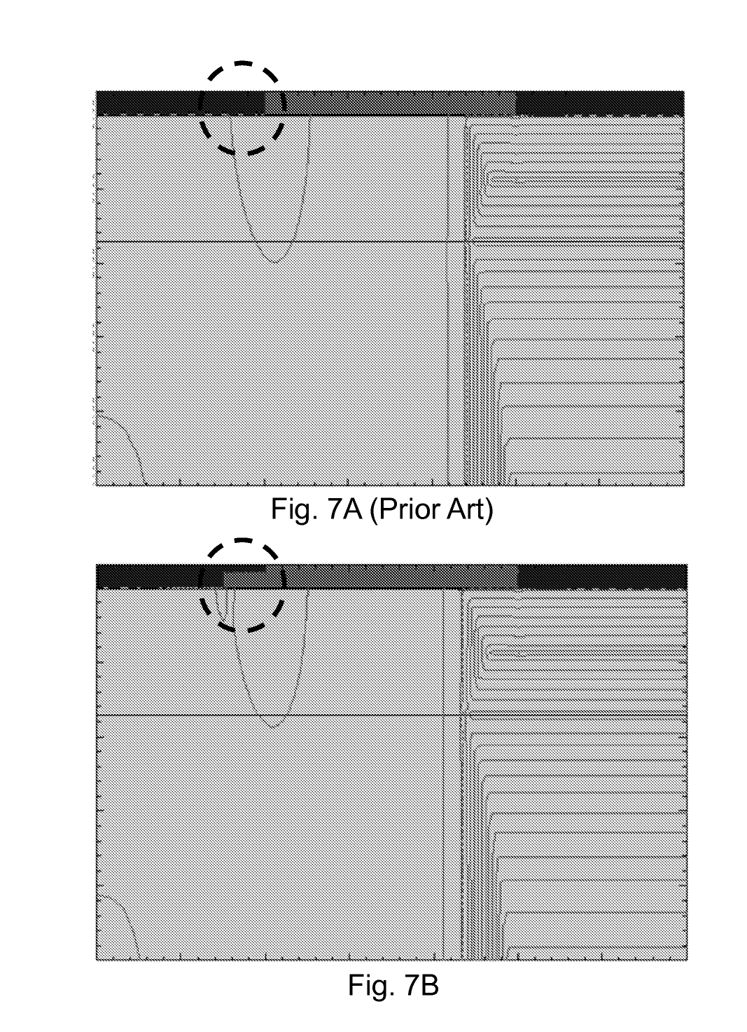

FIGS. 7A and 7B show simulation diagrams of two dimensional electric field from cross-section views of the SBDs according to the prior art and the present invention, respectively. As shown in FIGS. 7A and 7B, compared to the electric field according to the prior art, the electric field at the edge of the anode according to the present invention is split to two peaks with lower amplitudes under the same operation voltage. This indicates that the electric field of the SBD according to the present invention is mitigated, such that the breakdown voltage is enhanced, and the leakage current is suppressed.

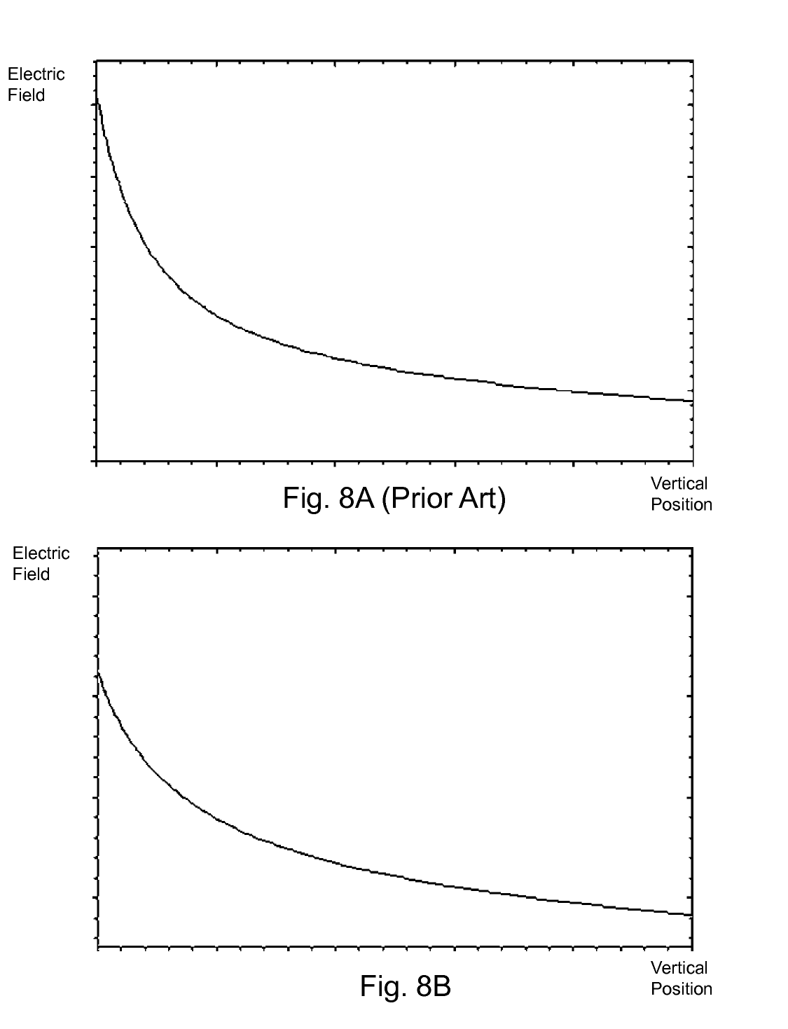

FIGS. 8A and 8B show simulation diagrams of electric field in vertical direction at the edge of the anode of the SBDs according to the prior art and the present invention, respectively. As shown in FIGS. 8A and 8B, compared to the electric field according to the prior art, the electric field at the edge of the anode according to the present invention has lower amplitude under the same operation voltage. This indicates that the electric field at the vertical direction of the SBD according to the present invention is also mitigated, such that the breakdown voltage is enhanced, and the leakage current is suppressed.

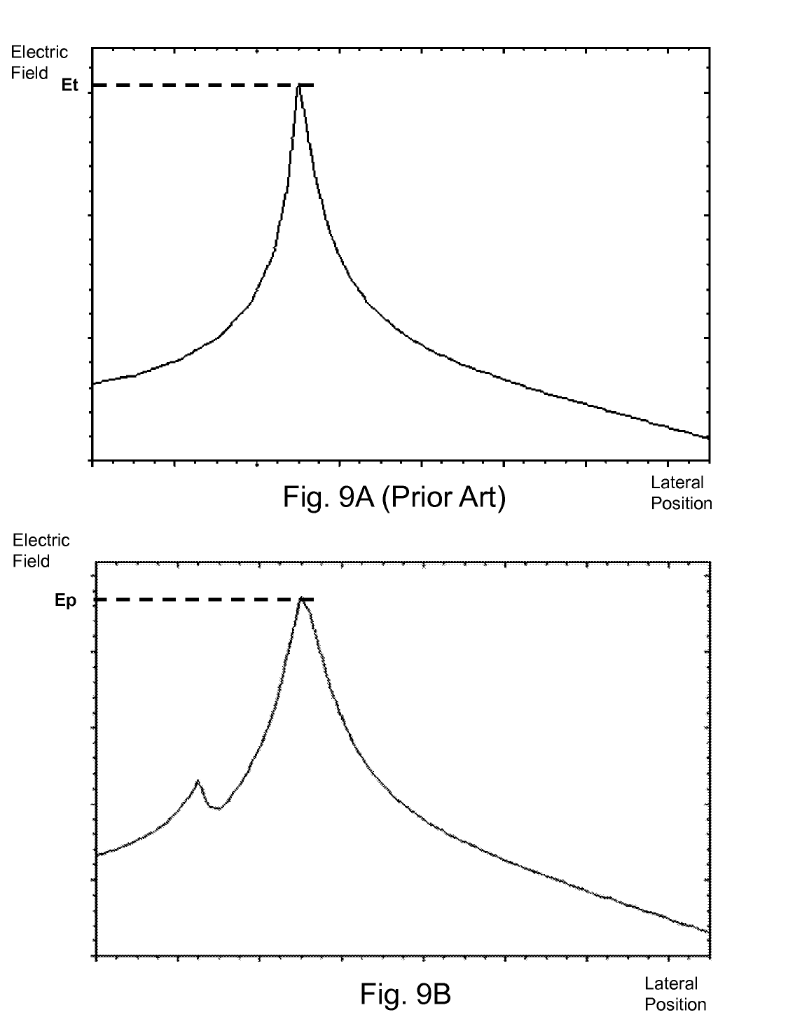

FIGS. 9A and 9B show simulation diagrams of electric field in lateral direction of the SBDs according to the prior art and the present invention, respectively. As shown in FIGS. 9A and 9B, compared to the electric field according to the prior art, the electric field at the lateral direction according to the present invention has lower amplitude under the same operation voltage, in particular at the edge of the anode, i.e., Ep<Et. This indicates that the electric field at the lateral direction of the SBD according to the present invention is also mitigated, such that the breakdown voltage is enhanced, and the leakage current is suppressed.

Note that, the thickness of the insulation layer of the SBD according to the present invention is preferably thinner than 1 micro-meter, and further preferably thinner than 0.1 micro-meter. This indicates that the function of the insulation layer of the present invention is to change the work function of the anode conductive layer, instead of isolating and decreasing the electric field by a thicker insulation layer.

The present invention has been described in considerable detail with reference to certain preferred embodiments thereof. It should be understood that the description is for illustrative purpose, not for limiting the scope of the present invention. Those skilled in this art can readily conceive variations and modifications within the spirit of the present invention. For example, other process steps or structures which do not affect the primary characteristics of the device may be added; as an example, the ohmic contact region for the cathode of the SBD may be defined and etched before forming the cathode conductive layer. In view of the foregoing, the spirit of the present invention should cover all such and other modifications and variations, which should be interpreted to fall within the scope of the following claims and their equivalents.

1. A Schottky barrier diode (SBD) formed on a substrate, comprising:
a gallium nitride (GaN) layer formed on the substrate;
an aluminum gallium nitride (AlGaN) layer formed on the GaN layer;
an insulation layer formed on the AlGaN layer;
an anode conductive layer formed partially on the insulation layer, wherein a Schottky contact is formed between a part of the anode conductive layer and the GaN layer or between a part of the anode conductive layer and the AlGaN layer, and another part of the anode conductive layer is separated from the AlGaN layer by the insulation layer; and
a cathode conductive layer, formed on the AlGaN layer, wherein an ohmic contact is formed between the cathode conductive layer and the GaN layer or between the cathode conductive layer and the AlGaN layer, and wherein the anode conductive layer is not directly connected to the cathode conductive layer.

2. The SBD of claim 1, wherein the insulation layer has a grid pattern from top view, and is formed between the anode conductive layer and the GaN layer or between the anode conductive layer and the AlGaN layer.

3. The SBD of claim 1, wherein the substrate includes an insulator substrate or a conductor substrate.

4. The SBD of claim 1, wherein the insulation layer has a thickness thinner than 1 micro-meter.

5. The SBD of claim 1, wherein the insulation Layer has a dielectric constant higher than 3.9.

6. A manufacturing method of a Schottky barrier diode (SBD), comprising:
forming a gallium nitride (GaN) layer on a substrate;
forming an aluminum gallium nitride (AlGaN) layer on the GaN layer;
forming an insulation layer on the AlGaN layer;
forming an anode conductive layer partially on the insulation layer, wherein a Schottky contact is formed between a part of the anode conductive layer and the GaN layer or between a part of the anode conductive layer and the AlGaN layer, and another part of the anode conductive layer is separated from the AlGaN layer by the insulation layer; and
forming a cathode conductive layer on the AlGaN layer, wherein an ohmic contact is formed between the cathode conductive layer and the GaN layer or between the cathode conductive layer and the AlGaN layer, and wherein the anode conductive layer is not directly connected to the cathode conductive layer.

7. The manufacturing method of claim 6, wherein the insulation layer has a grid pattern from top view, and is formed between the anode conductive layer and the GaN layer or between the anode conductive layer and the AlGaN layer.

8. The manufacturing method of claim 6, wherein the substrate includes an insulator substrate or a conductor substrate.

9. The manufacturing method of claim 6, wherein the insulation layer has a thickness thinner than 1 micro-meter.

10. The manufacturing method of claim 6, wherein the insulation layer has a dielectric constant higher than 3.9.
